(19) United States
(12) Patent Application Publication
(10) Pub. No.: US 2012/0326189 A1
(43) Pub. Date: Dec. 27, 2012

(54) Electrode Including Magnetic Material and Organic Light Emitting Device Including the Electrode

(75) Inventors: Joon-Gu Lee, Yongin-City (KR); Won-Jong Kim, Yongin-City (KR); Ji-Young Choung, Yongin-City (KR); Jin-Baek Choi, Yongin-City (KR); Yeon-Hwa Lee, Yongin-City (KR); Chang-Ho Lee, Yongin-City (KR); Il-Soo Oh, Yongin-City (KR); Hyung-Jun Song, Yongin-City (KR); Jin-Young Yun, Yongin-City (KR); Young-Woo Song, Yongin-City (KR); Jong-Hyuk Lee, Yongin-City (KR)

(73) Assignee: SAMSUNG MOBILE DISPLAY CO., LTD., Yongin-City (KR)

(21) Appl. No.: 13/283,821

(22) Filed: Oct. 28, 2011

(30) Foreign Application Priority Data
Jun. 22, 2011 (KR) 10-2011-0060794

(51) Int. Cl. H01L 33/60; H01L 33/42

(52) U.S. Cl. 257/98; 438/29; 257/99; 257/E33.064; 257/E33.072

(57) ABSTRACT

An electrode, which includes a magnetic material to improve the flow of charges, and an organic light emitting device using the electrode. The electrode for the organic light emitting device has an excellent charge injection property, so that it is possible to improve the efficiency of light emission of the organic light emitting device.

### CLAIM OF PRIORITY

This application makes reference to, incorporates the same herein, and claims all benefits accruing under 35 U.S.C. §119 from an application earlier filed in the Korean Intellectual Property Office on 22 Jun. 2011 and there duly assigned Serial No. 10-2011-0060794.

### BACKGROUND OF THE INVENTION

1. Field of the Invention

The present invention relates to an electrode, which contains a magnetic material to improve the flow of charges, and an organic light emitting device using the electrode.

2. Description of the Prior Art

An electroluminescent device, especially an organic light emitting device, which has been recently in the limelight of a display field, is a device using light generated when electrons and holes are combined and dissipate to emit the light.

The electroluminescent device basically includes an electrode for injecting holes, an electrode for injecting electrons, and a light emitting layer, and has a lamination structure in which the light emitting layer is interposed between the electrode for injecting the holes and the electrode for injecting the electrons. Among the electrodes of the electroluminescent device, the electrons are injected in the cathode, the holes are injected in the anode, and these charges are moved to each other in counter directions by an external electric field and are then combined in the light emitting layer, so that they dissipate while emitting light. Among the electroluminescent devices, a device including a light emitting layer formed of a monomer organic material or a polymer is especially called an “organic light emitting device”.

Conventionally, the anode, which is an electrode for the injection of holes, uses an electrode material having a high work function, such as gold (Au) or Indium-Tin-Oxide (ITO), and the cathode, which is an electrode for the injection of electrons, uses an electrode material having a low work function, such as magnesium (Mg) or lithium (Li).

Further, the electroluminescent device may employ a hole transport layer between the anode and the light emitting layer in order to enhance the hole transport, or an electron transport layer between the cathode and the light emitting layer in order to enhance the electron transport. In the organic light emitting device, the hole transport layer, the light emitting layer, and the electron transport layer are mainly formed of an organic material. Specifically, the hole transport layer is formed of a material having the property of a p-type semiconductor, and the electron transport layer is formed of a material having a property of an n-type semiconductor. It is general that the efficiency of the organic light emitting device is determined based on the efficiency of light emission. Therefore, in order to improve the efficiency of light emission of the organic light emitting device, various efforts and attempts have been conducted.

The efficiency of light emission of the organic light emitting device is generally affected by the easiness of the injection of electrons and holes, the degree of formation of singlet excitons, a position of light emission, and a use degree of triplet excitons. Therefore, in order to improve the efficiency of light emission of the organic light emitting device, a method in which the electron injection layer or the hole injection layer is inserted between the electrode and the light emitting layer to achieve the easy injection of the charges, a method in which a work function of the electrode is adjusted to a homo level or a lumo level of the light emitting layer to achieve the easy injection of the charges, or a method in which an organic material including a heavy element is added to the light emitting layer in order to change the triplet excitons which dissipate without emitting light to the singlet excitons which dissipate while emitting light was applied. However, the aforementioned methods have a limitation in an aspect of the device stability.

In the meantime, there also is a method for improving the efficiency of light emission of the organic light emitting device by increasing a reflectance of the electrode positioned in an opposite side of a light emitting surface of the organic light emitting device. Specifically, the electrode in the light emitting surface of the organic light emitting device is formed with a transparent electrode and the electrode positioned in the opposite side of the light emitting surface is formed with a reflective electrode, so that the light generated in the light emitting layer but radiated to the opposite side of the light emitting surface is reflected in the reflective electrode and thus to be radiated to the light emitting surface, thereby improving the efficiency of light emission.

An example of the reflective electrode, there is an electrode made of a metallic layer. However, if the metallic layer is used as the electrode as it is, there incurs a case in which the injection of the charges is not easy. Especially, when the reflective electrode including the metallic layer is used as the anode, the efficiency of the hole injection may be decreased.

In order to improve the problem incurred when the electrode made of the metallic layer is used as the anode, research on a structure in which a Transparent Conductive Oxide (TCO) layer is positioned on the metallic layer was conducted. When an electrode having a structure in which a thin film formed of a transparent conductive oxide, such as ITO, is formed on a metallic layer made of silver, the increase of the reflectance is contradictory to the efficiency of the charge injection, and it is necessary to improve the charge injection property for achieving the more excellent the efficiency of light emission.

### SUMMARY OF THE INVENTION

Accordingly, the present invention has been made to solve the above-mentioned problems occurring in the prior art, and the present invention provides an electrode for an organic light emitting device, which has both an excellent reflection property and a charge injection property.

Further, the present invention provides an organic light emitting device including the electrode.

Especially, the present invention provides an electrode for an organic light emitting device, which can control a spin direction of charges injected into a light emitting layer of the organic light emitting device to improve the charge injection property, and an organic light emitting device including the electrode.

In accordance with an aspect of the present invention, there is provided an electrode containing a magnetic material for an organic light emitting device.

The electrode for the organic light emitting device according to the present invention includes a metallic layer and a conductive transparent layer formed on the metallic layer. Here, the conductive transparent layer includes a transparent conductive oxide and a magnetic material. The transparent conductive oxide may be simply called the ‘TCO’.

Further, the present invention provides an organic light emitting device including the electrode.

The electrode according to the present invention is applied to the organic light emitting device, so that it is possible to control a spin direction of charges injected to a light emitting layer formed of an organic material, thereby improving a charge injection property. When the organic light emitting device controls the spin direction of the charges, a possibility of the generation of single excitons within the light emitting layer is increased, so that it is possible to increase the light emitting limitation of the organic light emitting device.

According to an exemplary embodiment of the present invention, the metallic layer includes silver (Ag). The silver has an excellent reflection property, as well as an excellent conductivity, so that it may be applied to a reflective electrode. The silver may be applied to both an anode and to a cathode.

According to an exemplary embodiment of the present invention, a thickness of the metallic layer may be adjusted to a range from 500 Å to 1500 Å. As the metallic layer is thicker, the conductive property is superior, so that the charge injection property is improved and the reflection property is also improved. However, it is preferred that the metallic layer is thin for the compactness of the device, so that taking the conductivity property, the reflection property, and the compactness of the device into consideration, the thickness of the metallic layer is adjusted to a range from 500 Å to 1500 Å.

According to an exemplary embodiment of the present invention, the thickness of the conductive transparent layer is adjusted to a range from 50 Å to 150 Å.

The conductive transparent layer functions to supplement a work function of the metallic layer. Taking the compactness of the device and the function of supplementing the work function into consideration, the thickness of the conductive transparent layer is adjusted to a range from 50 Å to 150 Å.

The conductive transparent layer includes a transparent conductive oxide, and an example of the transparent conductive oxide includes ITO, AZO, IGO, GIZO, IZO, and ZnOₓ, one of which may be used or two or more of which may be combined and used. In addition to the aforementioned materials, an oxide which is transparent and has the conductivity may be adopted for the transparent conductive oxide.

A magnetic material included in the conductive transparent material includes, for example, Ni, Co, Fe, Mn, Bi, FeO—Fe₂O₃, NiO—Fe₂O₃, CuO—Fe₂O₃, MgO—Fe₂O₃, MnBi, MnSb, MnAs, MnO—Fe₂O₃, Y₃Fe₂O₃, CrO₂, and EuO, one of which may be used or two or more of which may be combined and used. In addition to the above magnetic materials, it is a matter of course a material having the magnetism can be used.

According to an exemplary embodiment of the present invention, a work function of the conductive transparent layer is adjusted to a range from 4.8 eV to 6.5 eV.

According to an exemplary embodiment of the present invention, content of the magnetic material included in the conductive transparent layer is 1% to 30% by weight of an entire weight of the conductive transparent layer. The magnetic material is included in the conductive transparent layer by an amount with which the work function of the conductive transparent layer has a value ranging from 4.8 eV to 6.5 eV.

According to an exemplary embodiment of the present invention, in the conductive transparent layer, the transparent conductive oxide forms a matrix and the magnetic material is doped in the matrix formed of the transparent conductive oxide.

According to an exemplary embodiment of the present invention, the conductive transparent layer is formed by a sputtering method or a deposition method with raw materials including both the transparent conductive oxide and the magnetic material.

According to an exemplary embodiment of the present invention, the conductive transparent layer has a structure in which a thin film made of the magnetic material is disposed on a surface of a thin film made of the transparent conductive oxide. Here, the thin film made of the magnetic material may have a thickness ranging from 5 Å to 50 Å. Further, the thin film made of the transparent conductive oxide may have a thickness ranging from 45 Å to 100 Å.

According to an exemplary embodiment of the present invention, the aforementioned electrode may be applied to the reflective electrode of the organic light emitting device. Further, According to an exemplary embodiment of the present invention, the aforementioned electrode may be usefully applied to the anode of the organic light emitting device.

In accordance with another aspect of the present invention, there is provided a method for manufacturing an electrode for an organic light emitting device. The method includes the steps of forming a metallic layer on a substrate and forming a conductive transparent layer on the metallic layer. Here, the step of forming the conductive transparent layer comprises a sputtering process or a deposition process using raw materials including both a transparent conductive oxide and a magnetic material.

According to an exemplary embodiment of the present invention, the step of forming the conductive transparent layer includes the steps of forming a thin film made of the transparent conductive oxide and forming a thin film made of the magnetic material on the thin film made of the transparent conductive oxide.

According to an exemplary embodiment of the present invention, in the step of forming the conductive transparent layer, the sputtering process or the deposition process is performed using the transparent conductive oxide and the magnetic material at the same time to form a matrix using the transparent conductive material, and the magnetic material is doped in the matrix formed of the transparent conductive oxide.

In accordance with another aspect of the present invention, there is provided a cathode containing a metal and a magnetic material for an organic light emitting device.

According to an exemplary embodiment of the present invention, in the cathode for the organic light emitting device, the metal may include at least one among Ag, MgAg, and AgYg. Further, the magnetic material may include at least one selected from a group constituting Ni, Co, Fe, Mn, Bi, FeO—Fe₂O₃, NiO—Fe₂O₃, CuO—Fe₂O₃, MgO—Fe₂O₃, MnBi, MnSb, MnAs, MnO—Fe₂O₃, Y3 Fe₂O₃, CrO₂, and EuO.

According to an exemplary embodiment of the present invention, in the cathode for the organic light emitting device, the metal forms a matrix and the magnetic material is doped in the matrix formed of the metal.

According to an exemplary embodiment of the present invention, the cathode for the organic light emitting device may have a structure in which the metal forms a metallic layer and the magnetic material is disposed on the metallic layer in a form of a thin film.

According to an exemplary embodiment of the present invention, the thin film of the magnetic material may have a thickness ranging from 5 Å to 50Å, and the metallic material may have a thickness ranging from 45 Å to 250 Å.

According to an exemplary embodiment of the present invention, the cathode is a transparent electrode.

In accordance with another aspect of the present invention, there is provided an organic light emitting device including the aforementioned electrode.

According to an exemplary embodiment of the present invention, the organic light emitting device includes: a substrate; a first electrode formed on the substrate; an organic layer formed on the first electrode; and a second electrode formed on the organic layer. Here, the organic layer includes at least one layer including a light emitting layer, and one of the first electrode and the second electrode is an electrode including a metallic layer and a conductive transparent layer formed on the metallic layer. Further, the conductive transparent layer includes a transparent conductive oxide and a magnetic material.

In the organic light emitting device according to the present invention, the electrode including the metallic layer and the conductive transparent layer formed on the metallic layer is the same as the aforementioned electrode for the organic light emitting device.

According to an exemplary embodiment of the present invention, the electrode including the metallic layer and the conductive transparent layer formed on the metallic layer is the first electrode.

According to an exemplary embodiment of the present invention, the electrode including the metallic layer and the conductive transparent layer formed on the metallic layer is the first electrode formed on the substrate and has a function as a reflective electrode. According to an exemplary embodiment of the present invention, the first electrode is an anode.

According to an exemplary embodiment of the present invention, the other one of the first electrode and the second electrode is a cathode comprising a metal and a magnetic material. That is, in the organic light emitting device of the present invention, the first electrode is a anode and includes the metallic layer and the conductive transparent layer formed on the metallic layer, and the second electrode is a cathode including the metal and the magnetic material.

According to an exemplary embodiment of the present invention, a cathode including the metal and the magnetic material is a transparent electrode.

The electrode for the organic light emitting device according to the present invention has an excellent charge injection property. Therefore, when such an electrode is used for an electrode of the organic light emitting device, it is possible to increase the efficiency of light emission of the organic light emitting device. Further, when the electrode for the organic light emitting device according to the present invention is used as the reflective electrode, it is possible to obtain the excellent reflection property. In the present invention, by employing the electrode to the organic light emitting device, the present invention can control the spin direction of the charges injected into the light emitting layer of the organic light emitting device and improve the charge injection property, so that it is possible to improve the efficiency of the organic light emitting device.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a schematic diagram illustrating the concept of a structure of an organic light emitting device in which the present invention is applied;

FIG. 2 is a schematic diagram illustrating a structure of an organic layer in the organic light emitting device of FIG. 1 in more detail;

FIG. 3 is a schematic diagram illustrating an example of a structure of an electrode for an organic light emitting device;

FIG. 4 is a schematic diagram illustrating a structure of an electrode for an organic light emitting device according to an example of the present invention;

FIG. 5 is a schematic diagram illustrating a structure of an electrode for an organic light emitting device according to another example of the present invention;

FIG. 6 is a schematic diagram illustrating a structure of an electrode for an organic light emitting device according to another example of the present invention;

FIG. 7 is a schematic diagram illustrating a structure of an electrode for an organic light emitting device according to another example of the present invention;

FIG. 8 is a graph representing measurement results of a reflectance of a anode according to a wavelength in the organic light emitting devices manufactured in an example and a comparative example, respectively; and

FIG. 9 is a graph illustrating measurement results of a current density according to a voltage in the organic light emitting devices manufactured in an example and a comparative example, respectively.

### DETAILED DESCRIPTION OF THE INVENTION

Hereinafter, the present invention will be described in more detail with reference to the specific examples and a comparative embodiment, and the accompanying drawings. However, the scope of the present invention is not limited to the following examples or drawings.

In the meantime, each element, its shape, etc. in a drawing may be simply illustrated or exaggerated for helping the understanding. The same reference numerals are used to designate the same or similar components in the entire descriptions.

Further, in the following description, when it is said that a layer is “on” another layer or a substrate, it will be understood that the layer is positioned either directly on said another layer or the substrate, or above said another layer or the substrate with a third layer positioned between them.

FIG. 1 is a schematic diagram illustrating the concept of an organic light emitting device.

Referring to FIG. 1, the organic light emitting device has a basic structure in which a first electrode 20 is formed on a substrate 10, an organic layer 30 is formed on the first electrode, a second electrode 40 is formed on the organic layer 30. As can be seen above, the organic layer 30 is interposed between the first electrode 20 and the second electrode 40. A light emitting layer, in which holes and electrons are combined and dissipate while emitting the light, is included in the organic layer 30. One of the first electrode 20 and the second electrode 40 is an anode for injecting the holes and the other is a cathode for injecting the electrons.

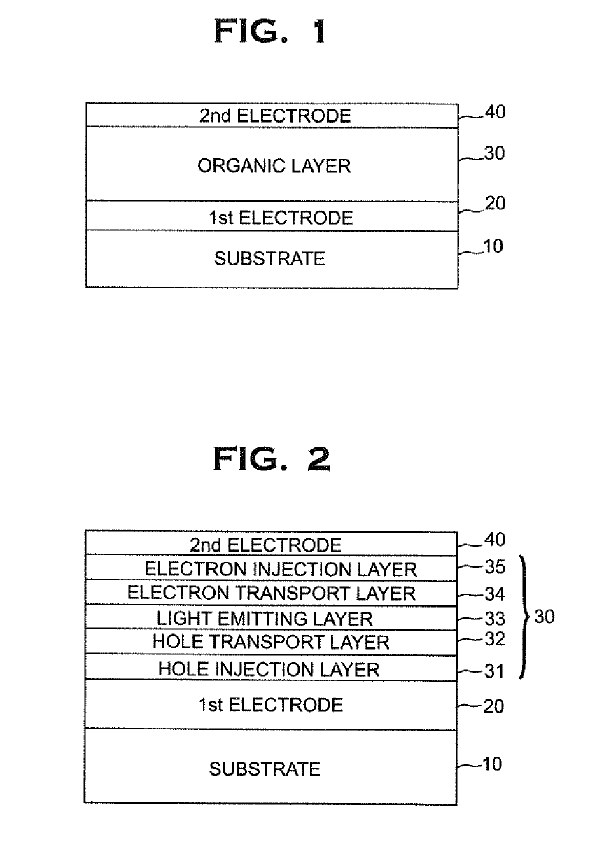

FIG. 2 is a diagram illustrating an example of the organic layer 30 having a lamination structure including multiple layers in the organic light emitting device. The organic layer 30 includes a hole injection layer, a hole transport layer, a light emitting layer, an electron transport layer, and an electron injection layer, which are sequentially formed on the anode. When the first electrode is the anode, the hole injection layer 31, the hole transport layer 32, the light emitting layer 33, the electron transport layer 34, and the electron injection layer 35 are sequentially formed on the first electrode 20.

However, when the first electrode 20 is the cathode, the electron injection layer, the electron transport layer, the light emitting layer, the hole transport layer, and the hole injection layer are sequentially formed on the first electrode 20.

For reference, there are many cases in which the electron injection layer is formed of metallic elements or their combination, not the organic material, so that the electron injection layer may not be included in the organic layer, but may be discriminated as a separate layer.

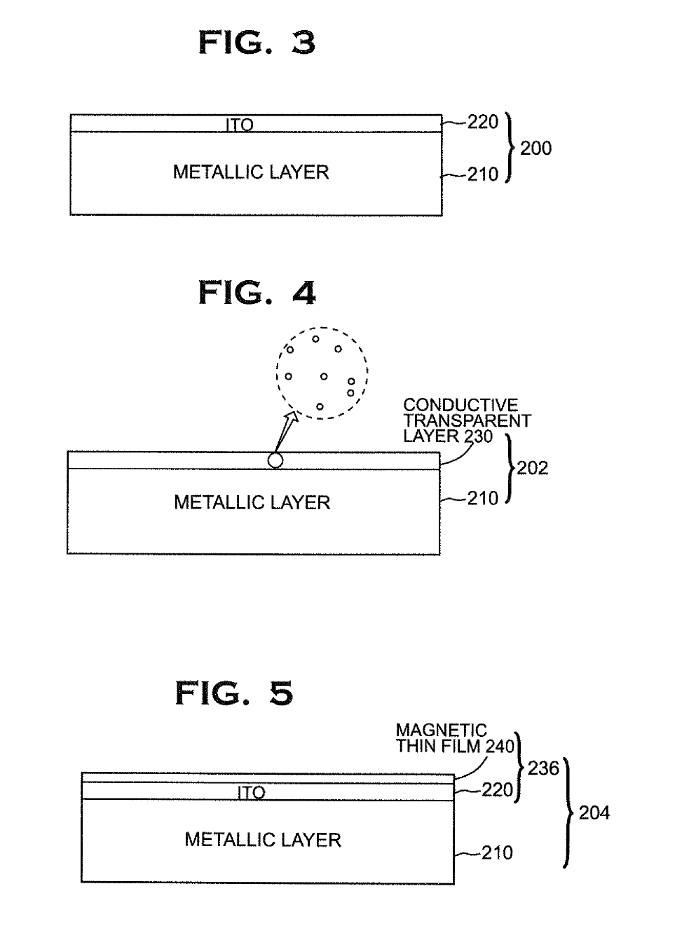

FIG. 3 illustrates an electrode 200 having a structure in which a thin film 220 formed of a transparent conductive oxide, such as ITO, is formed on a metallic layer 210 made of silver. However, in the electrode shown in FIG. 3, the increase of the reflectance is contradictory to the efficiency of the charge injection, and it is necessary to improve the charge injection property for achieving the more excellent the efficiency of light emission.

FIG. 4 is a diagram schematically illustrating an electrode 202 for an organic light emitting device containing a magnetic material according to an example of the present invention. Here, the electrode 202 for the organic light emitting device includes a metallic layer 210 and a conductive transparent layer 230 formed on the metallic layer 210. The conductive transparent layer 230 includes a transparent conductive oxide 231 and a magnetic material 232.

In the conductive transparent layer 230 of the electrode 202 for the organic light emitting device shown in FIG. 4, the magnetic material 232 is doped in a matrix formed of the transparent conductive oxide 231.

FIG. 5 illustrates the electrode for the organic light emitting device according to another example of the present invention.

In FIG. 5, an electrode 204 for an organic light emitting device contains a metallic layer 210 and a conductive transparent layer 236. The conductive transparent layer 236 has a structure in which a thin film 240 made of a magnetic material is positioned on a surface of a thin film 220 made of the transparent conductive oxide.

In FIGS. 4 and 5, the conductive transparent layer may be formed by a sputtering method or a deposition method using the raw materials including the transparent conductive oxide and the magnetic material

Specifically, the electrode 202 or 204 for the organic light emitting device according to the present invention may be manufactured by forming the metallic layer 210 on a substrate (not shown) and then forming the conductive transparent layer 230 or 236 on the metallic layer 210. Here, the substrate may be a substrate of the organic light emitting device or may be separately prepared for the manufacturing of the electrode. In the meantime, the sputtering process or the deposition process may be applied in order to form the conductive transparent layer.

According to the example of FIG. 4, it is possible to perform the sputtering or the deposition of the transparent conductive oxide and the magnetic material at the same time in order to form the conductive transparent layer 230. Specifically, when the co-deposition is performed using the transparent conductive oxide and the magnetic material at the same time, a deposited layer in which the transparent conductive oxide and the magnetic material are mixed is formed. Similarly, when the mixed sputtering is performed using the transparent conductive oxide and the magnetic material at the same time, a sputtering layer in which the transparent conductive oxide and the magnetic material are mixed is formed.

As a result of the co-deposition or the mixed sputtering, the matrix is formed of the transparent conductive oxide 231 and the magnetic material 232 is doped in the matrix formed of the transparent conductive oxide 231. Such an electrode has a structure illustrated in FIG. 4.

According to the example of FIG. 5, in a step of forming the conductive transparent layer 236, the thin film 220 made of the transparent conductive oxide may be formed on the metallic layer 210 by using the transparent conductive oxide and then the thin film 240 made of the magnetic material may be formed on the surface of the thin film 220. The sputtering or the deposition may be applied to the forming of the thin film 220 made of the transparent conductive oxide and the thin film 240 made of the magnetic material.

According to the example of FIG. 5, the thin film 240 made of the magnetic material may have the thickness ranging from 5 Å to 50 Å, and the thin film 220 made of the transparent conductive oxide may have the thickness ranging from 45 Å to 100 Å.

The electrode for the organic light emitting device according to the present invention includes the magnetic material, so that it is possible to control the spin direction of the charges injected into the light emitting layer made of the organic material, thereby improving the charge injection property. By controlling the spin direction of the charges in the organic light emitting device as described above, it is possible to increase the possibility of generation of the singlet excitons within the light emitting layer and it is thus possible to increase the limitation, to which the organic light emitting device can emit light.

In this regard, according to an exemplary embodiment of the present invention, the magnetic material included in the electrode has a uniform magnetization direction (or the spin direction). When the magnetic material included in the electrode is magnetized in a uniform direction, only the charges having the spin direction corresponding to the magnetization direction can be injected into the light emitting layer. By using the electrode containing the magnetic material, the present invention can control the spin direction of the charges injected into the light emitting layer, so that it is possible to improve the efficiency of light emission of the organic light emitting device.

Specifically, when the magnetization direction, i.e. the spin direction, of the magnetic material included in the electrode is an upward direction, the charges having the upward spin direction pass the electrode without resistance, but the charges having the downward spin direction receive the resistance, to have a difficulty in passing the electrode. In this respect, the charges passing the electrode have the upward spin direction. Similarly, when the spin direction of the magnetic material included in the electrode is a downward direction, the charges passing the electrode have the downward spin direction. As such, when only the charges in a particular spin direction are selectively injected into the light emitting layer, the efficiency of light emission is increased.

According to an example of the present invention, the metallic layer 210 includes silver (Ag). The silver has not only an excellent conductivity but also an excellent reflection property. Therefore, the electrode having the metallic layer formed of silver may be used as the reflective electrode. The electrode having the metallic layer formed of silver may be applied to both the anode and the cathode.

According to an example of the present invention, a thickness of the metallic layer 210 may be adjusted to a range from 500 Å to 1500 Å. According to an example of the present invention, the thickness of the conductive transparent layer 230 or 236 is adjusted to a range from 50 Å to 150 Å. The conductive transparent layer 230 or 236 has a function of supplementing the work function of the metallic layer 210.

An example of the transparent conductive oxide included in the conductive transparent layer 230 or 236 includes ITO, ZAO, IGO, GIZO, IZO, and ZnOₓ, one of which may be used or two or more of which may be combined and used.

An example of the magnetic material included in the conductive transparent layer 230 or thin film 240 includes Ni, Co, Fe, Mn, Bi, FeO—Fe₂O₃, NiO—Fe₂O₃, CuO—Fe₂O₃, MgO—Fe₂O₃, MnBi, MnSb, MnAs, MnO—Fe₂O₃, Y₃Fe₂O₃, CrO₂, and EuO, one of which may be used or two or more of which may be combined and used.

According to an example of the present invention, the work function of the conductive transparent layer 230 or 236 may be adjusted within a range from 4.8 eV to 6.5 eV. In this case, the electrode including the conductive transparent layer is the anode.

According to an example of the present invention, content of the magnetic material included in the conductive transparent layer 230 or thin film 240 is 1% to 30% by weight of the entire weight of the conductive transparent layer 230 or 236. The content of the magnetic material is adjusted to a degree in which the work function of the conductive transparent layer 230 or 236 is within the range of 4.8 eV to 6.5 eV.

According to an example of the present invention, the aforementioned electrode has the excellent reflection property. Therefore, the electrode may be applied to the reflective electrode of the organic light emitting device. Especially, the electrode may be usefully applied to the anode of the organic light emitting device.

A method for manufacturing the electrode for the organic light emitting device according to the present invention is the same as the above description.

The cathode 40 for the organic light emitting device has a structure in which the metal forms the matrix and the magnetic material is doped in the matrix formed of the metal.

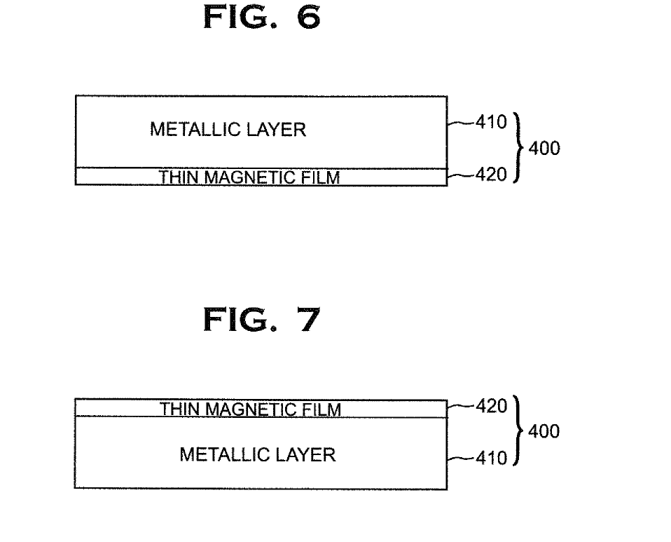

FIG. 6 and FIG. 7 are schematic diagrams illustrating a structure of an electrode for an organic light emitting device according to another example of the present invention.

The present invention provides a cathode 400 for the organic light emitting device including the metal and the magnetic material. In the cathode for the organic light emitting device, the metal includes at least one of Ag, MgAg, and AgYg. Further, the magnetic material may include at least one selected from the group consisting of Ni, Co, Fe, Mn, Bi, FeO—Fe₂O₃, NiO—Fe₂O₃, CuO—Fe₂O₃, MgO—Fe₂O₃, MnBi, MnSb, MnAs, MnO—Fe₂O₃, Y₃Fe₂O₃, CrO₂, and EuO.

The cathode 400 of FIGS. 6 and 7 for the organic light emitting device has a structure in which the metal forms a metallic layer 410 and the magnetic material is positioned on the surface of the metallic layer in a form of a thin film 420. Here, the thin film 420 made of the magnetic material may have a thickness ranging from 5 Å to 50 Å, and the metallic layer 410 may have the thickness ranging from 45 Å to 250 Å. The thin film 420 made of the magnetic material may be positioned beneath the lower surface of the metallic layer 410 (refer to FIG. 6) or on the upper surface of the metallic layer 410 (refer to FIG. 7).

When the metallic layer 410 has the thickness within a range from 45 Å to 250 Å, the cathode for the organic light emitting device can be a transparent electrode.

The present invention provides the organic light emitting device including the electrode.

The organic light emitting device according to the example of the present invention includes the substrate 10, the first electrode 20 formed on the substrate, the organic layer 30 formed on the first electrode, and the second electrode 40 formed on the organic layer (refer to FIG. 1).

Here, the organic layer 30 includes at least one layer including the light emitting layer 33 (refer to FIG. 2). According to the example of the present invention, the organic layer 30 includes a hole injection layer, a hole transport layer, the light emitting layer, an electron transport layer, and an electron injection layer, which are sequentially formed on the anode.

Referring to FIG. 2, when the first electrode 20 is the anode, the hole injection layer 31, the hole transport layer 32, the light emitting layer 33, the electron transport layer 34, and the electron injection layer 35 are sequentially formed on the first electrode 20. However, when the second electrode 40 is the anode, layer 35 is the hole injection layer, layer 34 is the hole transport layer, layer 32 is the electron transport layer, and layer 31 is the electron injection layer 31.

One of the first electrode and the second electrode in the organic light emitting device according to an example of the present invention is the electrode 202 including the metallic layer 210 and the conductive transparent layer 230 formed on the metallic layer 210. The conductive transparent layer 230 includes the transparent conductive oxide (ITO) 231 and the metallic material 232 (referring to FIG. 4), which has been already described.

On the other hand, one of the first electrode and the second electrode in the organic light emitting device according to another example of the present invention is the electrode 204 for an organic light emitting device and contains the metallic layer 210 and the conductive transparent layer 236. The conductive transparent layer 236 has a structure in which the thin film 240 made of a magnetic material is positioned on a surface of the thin film 220 made of the transparent conductive oxide (referring to FIG. 5), which has been already described.

According to an example of the present invention, the electrode 202 or 204 may be the first electrode 20 of FIGS. 1 and 2. In this case, the electrode 202 or 204 including the metallic layer and the conductive transparent layer formed on the metallic layer may have a function of the reflective electrode serving as the first electrode 20 formed on the substrate. At this time, the first electrode 20 is the anode.

According to an example of the present invention, the other of the first electrode and the second electrode is the cathode 400 including the metal and the magnetic material.

However, according to an example of the present invention, it is possible to configure that the first electrode 20 is the cathode and the second electrode 40 is the anode including the metal and the magnetic material.

According to an example of the present invention, the cathode including the metal and the magnetic material may be the transparent electrode.

As an embodiment of the present invention, the metallic layer 210 was formed on a glass substrate 10 by using silver and the transparent conductive layer 230 was formed on the metallic layer 210. The transparent conductive layer 230 was formed by doping Nikel (Ni), which is a magnetic material, in the ITO, which is a kind of the transparent conductive oxide, with the doping weight ratio of Ni:ITO=5:95, while forming a film with a thickness of 70 Å. The electrode including the metallic layer 210 and the transparent conductive layer 230 was formed as the anode.

And then, the hole injection layer, the hole transport layer, the light emitting layer, the electron transport layer, and the electron injection layer were sequentially film-formed on the anode and an MgAg layer serving as the cathode was formed, so that the an OLED device was manufactured.

For comparison, a blue OLED device was manufactured in an identical manner as that of the embodiment described above, except that the blue OLED has an anode, which includes a metallic layer 210 formed of Silver and an ITO film 220 including no magnetic material formed with a thickness of 70 Å on the metallic layer 210. The blue OLED manufactured for comparison was a comparative embodiment.

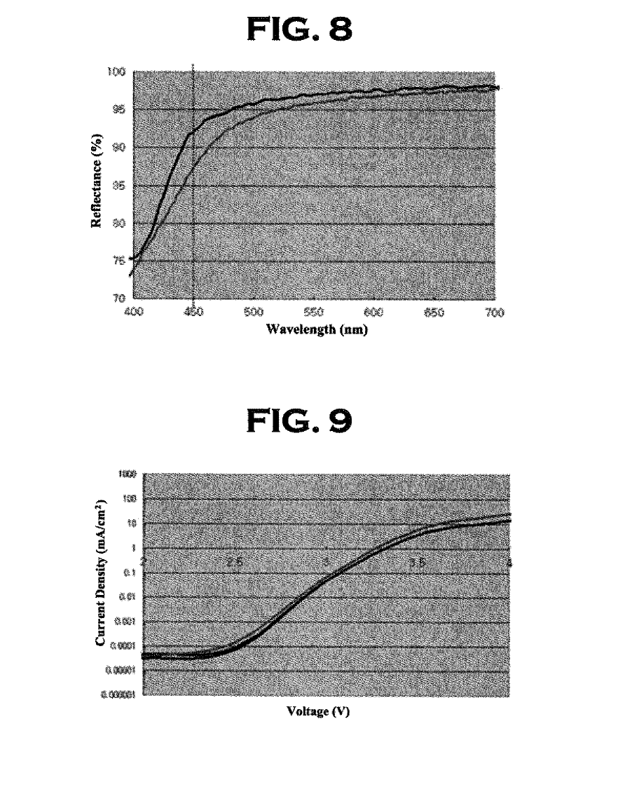

FIG. 8 shows the results of the reflectance measured according to the wavelength in the anode of the blue OLED devices manufactured in the embodiment and the comparative embodiment, and FIG. 9 shows the results of the current density measured according to the voltage. In FIGS. 8 and 9, the lighter solid lines represent the result of the embodiment and the blacker solid lines represent the result of the comparative embodiment.

In FIG. 8, it can be identified that the reflectance in the wavelength of 450 nm of the embodiment is lower by 5% than that of the comparative embodiment. However, in FIG. 9, it can be identified that the current density is improved. Such a result shows the fact that the charge flow is rather improved by the spin control of the charges in the anode. It can be noted that the efficiency of the blue OLED device according to the embodiment is improved by 10% in comparison with the comparative embodiment.

Although the present invention has been described with reference to the limited example and drawings, the present invention is not limited thereto and those skilled in the art will appreciate that various modifications, additions and substitutions are possible, without departing from the scope and spirit of the invention as disclosed in the accompanying claims.

What is claimed is:

1. An electrode for an organic light emitting device, comprising:
a metallic layer; and
a conductive transparent layer formed on the metallic layer, the conductive transparent layer comprising a transparent conductive oxide and a magnetic material.

2. The electrode as claimed in claim 1, the metallic layer comprises silver (Ag).

3. The electrode as claimed in claim 1, the metallic layer has a thickness ranging from 500 Å to 1500 Å.

4. The electrode as claimed in claim 1, the conductive transparent layer has a thickness ranging from 50 Å to 150 Å.

5. The electrode as claimed in claim 1, the conductive transparent layer has a work function ranging from 4.8 eV to 6.5 eV.

6. The electrode as claimed in claim 1, the transparent conductive oxide comprises at least one selected from the group consisting of ITO, AZO, IGO, GIZO, IZO, and ZnOₓ.

7. The electrode as claimed in claim 1, the magnetic material comprises at least one selected from the group consisting of Ni, Co, Fe, Mn, Bi, FeO—Fe₂O₃, NiO—Fe₂O₃, CuO—Fe₂O₃, MgO—Fe₂O₃, MnBi, MnSb, MnAs, MnO—Fe₂O₃, Y₃Fe₂O₃, CrO₂, and EuO.

8. The electrode as claimed in claim 1, the magnetic material content included in the conductive transparent layer is 1% to 30% by weight of an entire weight of the conductive transparent layer.

9. The electrode as claimed in claim 1, the transparent conductive oxide, in the conductive transparent layer, forms a matrix and the magnetic material is doped in the matrix formed of the transparent conductive oxide.

10. The electrode as claimed in claim 9, the conductive transparent layer is formed by a sputtering or a deposition with raw materials comprising the transparent conductive oxide and the magnetic material.

11. The electrode as claimed in claim 1, the conductive transparent layer comprises a thin film made of the magnetic material disposed on a thin film made of the transparent conductive oxide.

12. The electrode as claimed in claim 11, the thin film made of the magnetic material has a thickness ranging from 5 Å to 50 Å.

13. The electrode as claimed in claim 11, the thin film made of the transparent conductive oxide has a thickness ranging from 45 Å to 100 Å.

14. The electrode as claimed in claim 1, the electrode is a reflective electrode.

15. The electrode as claimed in claim 1, the electrode is an anode.

16. A method for manufacturing an electrode for an organic light emitting device, the method comprising steps of:
forming a metallic layer on a substrate; and
forming a conductive transparent layer on the metallic layer, the conductive transparent layer being formed by a sputtering process or a deposition process using raw materials comprising a transparent conductive oxide and a magnetic material.

17. The method as claimed in claim 16, the step of forming the conductive transparent layer comprises steps of:
forming a thin film made of the transparent conductive oxide on the metallic layer by using the transparent conductive oxide; and
forming a thin film made of the magnetic material on the thin film made of the transparent conductive oxide.

18. The method as claimed in claim 16, in the step of forming the conductive transparent layer, the sputtering process or the deposition process is performed using the transparent conductive oxide and the magnetic material at the same time to form a matrix by the transparent conductive material, and the magnetic material is doped in the matrix formed of the transparent conductive oxide.

19. A cathode for an organic light emitting device comprising a metal and a magnetic material.

20. The cathode as claimed in claim 19, the metal comprises at least one among Ag, MgAg, and AgYg.

21. The cathode as claimed in claim 19, the magnetic material comprises at least one selected from the group consisting of Ni, Co, Fe, Mn, Bi, FeO—Fe₂O₃, NiO—Fe₂O₃, CuO—Fe₂O₃, MgO—Fe₂O₃, MnBi, MnSb, MnAs, MnO—Fe₂O₃, Y₃Fe₂O₃, CrO₂, and EuO.

22. The cathode as claimed in claim 19, the metal forms a matrix and the magnetic material is doped in the matrix formed of the metal.

23. The cathode as claimed in claim 19, the metal forms a metallic layer and the magnetic material is disposed on the metallic layer in a form of a thin film.

24. The cathode as claimed in claim 23, the thin film of the magnetic material has a thickness ranging from 5 Å to 50 Å.

25. The cathode as claimed in claim 23, the metallic material has a thickness ranging from 45 Å to 250 Å.

26. The cathode as claimed in claim 19, the cathode is a transparent electrode.

27. An organic light emitting device comprising:
a substrate;
a first electrode formed on the substrate;
an organic layer formed on the first electrode; and
a second electrode formed on the organic layer, the organic layer comprises at least one layer comprising a light emitting layer,
one of the first electrode and the second electrode is an electrode comprising a metallic layer and a conductive transparent layer formed on the metallic layer, and
the conductive transparent layer comprises a transparent conductive oxide and a magnetic material.

28. The organic light emitting device as claimed in claim 27, the electrode comprising the metallic layer and the conductive transparent layer formed on the metallic layer is the first electrode.

29. The organic light emitting device as claimed in claim 28, the first electrode is a reflective electrode.

30. The organic light emitting device as claimed in claim 28, the first electrode is a anode.

31. The organic light emitting device as claimed in claim 27, one of the first electrode and the second electrode is a cathode comprising a metal and a magnetic material.

32. The organic light emitting device as claimed in claim 31, the cathode comprises a transparent electrode.

33. The organic light emitting device as claimed in claim 31, the electrode comprising the metal and the magnetic material is the second electrode.
